(19) United States
(12) Patent Application Publication
(10) Pub. No.: US 2010/0231273 A1
(43) Pub. Date: Sep. 16, 2010

(54) SEMICONDUCTOR DEVICE

(75) Inventor: Fumihiko TACHIBANA, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/540,639

(22) Filed: Aug. 13, 2009

(30) Foreign Application Priority Data
Mar. 10, 2009 (JP) 2009-056119

(51) Int. Cl. H03L 7/00

(52) U.S. Cl. 327/143

(57) ABSTRACT

A semiconductor device has a first MOS transistor being connected between a signal terminal and a first power supply line and having a gate connected to a second power supply line; a first capacitive element connected between the signal terminal and the second power supply line; a second MOS transistor being connected between the signal terminal and the second power supply line and having a gate connected to a first terminal; a third MOS transistor being connected between the first power supply line and the first terminal and having a gate connected to the second power supply line; a fourth MOS transistor being connected between the first terminal and a second terminal and having a gate connected to the second power supply line; a second capacitive element connected between the first power supply line and the second terminal; and a fifth MOS transistor being connected between the second terminal and the second power supply line.

### CROSS-REFERENCE TO RELATED APPLICATION

This application is based upon and claims the benefit of priority from the prior Japanese Patent Application No. 2009-56119, filed on Mar. 10, 2009, the entire contents of which are incorporated herein by reference.

### BACKGROUND OF THE INVENTION

1. Field of the Invention

The present invention relates to a semiconductor device for outputting a reset signal for resetting a state of a circuit.

2. Background Art

In a circuit using a substrate bias technique, a difference between a power supply voltage and a substrate voltage increases at power-on and may cause latchup. Thus at power-on, the substrate voltage has to be shunted to the power supply voltage.

In a power-on reset circuit of the prior art (for example, see Japanese Patent Laid-Open No. 2000-138348), the output of a voltage detecting circuit is set at “Low” level immediately after power-on. The voltage detecting circuit is made up of a resistance element and a capacitive element which are connected in series. In this state, the value of a counter for counting a signal of an oscillator and the value of a flip-flop are reset and the output of the flip-flop is set at “Low” level. After that, charge is accumulated in the capacitive element through the resistance element with the passage of time. When the output of the voltage detecting circuit reaches “High” level, the oscillator starts operating. When the value of the counter reaches a specified value, the CLK terminal of the flip-flop receives a signal and the output of the flip-flop becomes “High” level. The output of the flip-flop is used as a reset signal for a substrate bias generating circuit. Thus a substrate voltage can be shunted to a power supply voltage by performing a reset for a certain period of time at power-on.

However, in the power-on reset circuit of the prior art, charge remains in the capacitive element even after power-off, so that the reset signal is not set at “Low” level when the power supply is turned on again. Thus the output of the flip-flop is not reset.

In order to solve the problem, another power-on reset circuit of the prior art (for example, see Japanese Patent Laid-Open No. 09-270686) includes a discharging circuit (pMOS transistor).

The power-on reset circuit can reduce a voltage across a capacitive element to the threshold voltage of the pMOS transistor when the power supply is turned off.

However, when the pMOS transistor has a high threshold voltage, the power-on reset circuit cannot sufficiently reduce the voltage across the capacitive element, so that a reset signal is not properly generated.

### SUMMARY OF THE INVENTION

According to one aspect of the present invention, there is provided: a semiconductor device comprising:

a signal terminal;

an output terminal that outputs a reset signal according to a voltage of the signal terminal;

a first MOS transistor of a first conductivity type, the first MOS transistor being connected between the signal terminal and a first power supply line and having a gate connected to a second power supply line;

a first capacitive element connected between the signal terminal and the second power supply line;

a second MOS transistor of the first conductivity type, the second MOS transistor being connected between the signal terminal and the second power supply line and having a gate connected to a first terminal;

a third MOS transistor of the first conductivity type, the third MOS transistor being connected between the first power supply line and the first terminal and having a gate connected to the second power supply line;

a fourth MOS transistor of a second conductivity type, the fourth MOS transistor being connected between the first terminal and a second terminal and having a gate connected to the second power supply line;

a second capacitive element connected between the first power supply line and the second terminal; and

a fifth MOS transistor of the second conductivity type, the fifth MOS transistor being connected between the second terminal and the second power supply line and having a gate connected to the first power supply line.

According to another aspect of the present invention, there is provided: a semiconductor device comprising:

a signal terminal;

an output terminal that outputs a reset signal according to a voltage of the signal terminal;

a first MOS transistor of a first conductivity type, the first MOS transistor being connected between the signal terminal and a first power supply line and having a gate connected to a second power supply line;

a first capacitive element connected between the signal terminal and the second power supply line;

a second MOS transistor of the first conductivity type, the second MOS transistor being connected between the signal terminal and the second power supply line and having a gate connected to a first terminal;

a third MOS transistor of the first conductivity type, the third MOS transistor being connected between the first power supply line and the first terminal and having a gate connected to the second power supply line;

a fourth MOS transistor of a second conductivity type, the fourth MOS transistor being connected between the first terminal and a second terminal and having a gate connected to the second power supply line;

a second capacitive element connected between the first power supply line and the second terminal; and

a fifth MOS transistor being connected between the second terminal and the second power supply line and being diode-connected.

### BRIEF DESCRIPTION OF THE DRAWINGS

FIG. 1 is a circuit diagram showing the configuration of a power-on reset circuit (semiconductor device) 100 according to a first embodiment which is an aspect of the present invention;

FIG. 2 is a diagram showing an example of the operation of the voltage generating section A in the power-on reset circuit 100 of FIG. 1;

FIG. 3 is a waveform chart showing an example of the signal waveforms of the power-on reset circuit 100 in FIG. 1 when the power supply is repeatedly turned on and off;

FIG. 4 is a circuit diagram showing the configuration of a power-on reset circuit (semiconductor device) 200 according to the second embodiment which is an aspect of the present invention;

FIG. 5 is a circuit diagram showing the configuration of a power-on reset circuit (semiconductor device) 300 according to the third embodiment which is an aspect of the present invention;

FIG. 6 is a circuit diagram showing the configuration of a power-on reset circuit (semiconductor device) 400 according to the fourth embodiment which is an aspect of the present invention; and

FIG. 7 is a circuit diagram showing the configuration of a power-on reset circuit (semiconductor device) 500 according to the fifth embodiment which is an aspect of the present invention.

### DETAILED DESCRIPTION

The following will describe embodiments to which the present invention is applied with reference to the accompanying drawings.

In the following explanation, a MOS transistor of a first conductivity type is a pMOS transistor, a MOS transistor of a second conductivity type is an nMOS transistor, a first power supply line is connected to a power supply, and a second power supply line is connected to a ground.

The present invention is similarly applicable also when the MOS transistor of the first conductivity type is an nMOS transistor, the MOS transistor of the second conductivity type is a pMOS transistor, the first power supply line is connected to the ground, and the second power supply line is connected to the power supply.

### First Embodiment

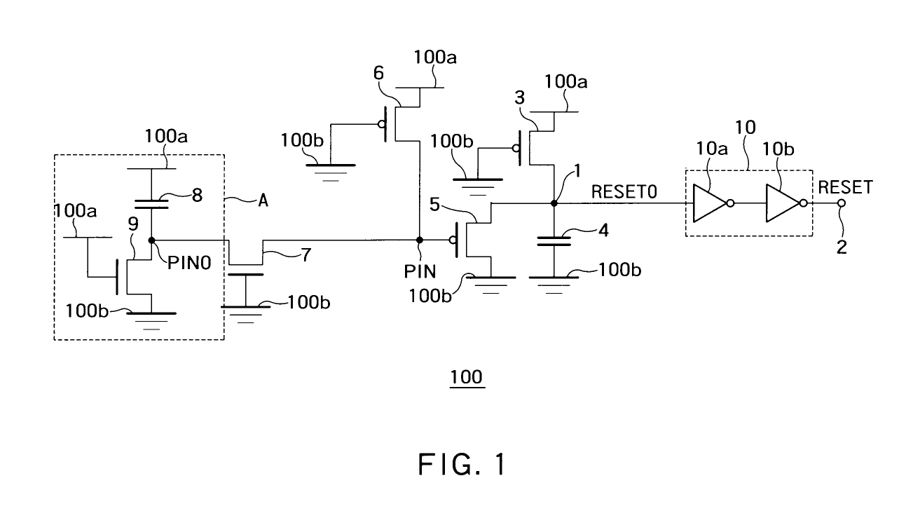

FIG. 1 is a circuit diagram showing the configuration of a power-on reset circuit (semiconductor device) 100 according to a first embodiment which is an aspect of the present invention.

As shown in FIG. 1, the power-on reset circuit 100 includes a signal terminal 1, an output terminal 2, a first MOS transistor 3, a first capacitive element 4, a second MOS transistor 5, a third MOS transistor 6, a fourth MOS transistor 7, a second capacitive element 8, a fifth MOS transistor 9, and an inverter circuit 10.

To the output terminal 2, a reset signal RESET is outputted according to a voltage RESET0 of the signal terminal 1.

The first MOS transistor 3 is a MOS transistor (pMOS transistor) of a first conductivity type. The first MOS transistor 3 is connected between the signal terminal 1 and a first power supply line 100a and has the gate connected to a second power supply line 100b.

The first capacitive element 4 is connected between the signal terminal 1 and the second power supply line 100b.

The second MOS transistor 5 is a MOS transistor of the first conductivity type. The second MOS transistor 5 is connected between the signal terminal 1 and the second power supply line 100b and has the gate connected to a first terminal PIN.

The third MOS transistor 6 is a MOS transistor of the first conductivity type. The third MOS transistor 6 is connected between the first power supply line 100b and the first terminal PIN has the gate connected to the second power supply line 100b.

The fourth MOS transistor 7 is a MOS transistor (nMOS transistor) of a second conductivity type. The fourth MOS transistor 7 is connected between the first terminal PIN and a second terminal PIN0 and has the gate connected to the second power supply line 100b.

The second capacitive element 8 is connected between the first power supply line 100a and the second terminal PIN0.

The fifth MOS transistor 9 is a MOS transistor of the second conductivity type. The fifth MOS transistor 9 is connected between the second terminal PIN0 and the second power supply line 100b and has the gate connected to the first power supply line 100a.

The fifth MOS transistor 9 and the second capacitive element 8 constitute a voltage generating section A for generating a negative voltage when the power supply is turned off.

The inverter circuit 10 has the input side connected to the signal terminal 1 and the output side connected to the output terminal 2, and includes inverters 10a and 10b connected in series. The inverter circuit 10 outputs the reset signal RESET to the output terminal 2 according to the voltage RESET0 of the signal terminal 1.

The first to third MOS transistors 3, 5, and 6 preferably have the same threshold voltage Vthp. Further, the fourth and fifth MOS transistors 7 and 9 preferably have the same threshold voltage Vthn. In other words, the MOS transistors of the same conductivity type preferably have the same threshold voltage.

The following will describe an example of an operation of outputting the reset signal from the power-on reset circuit 100 configured thus.

In the following explanation, a power supply voltage VDD is equal to a ground voltage VSS at power-off, and the power supply voltage VDD is equal to a specified value VDDH (>the ground voltage VSS) at power-on.

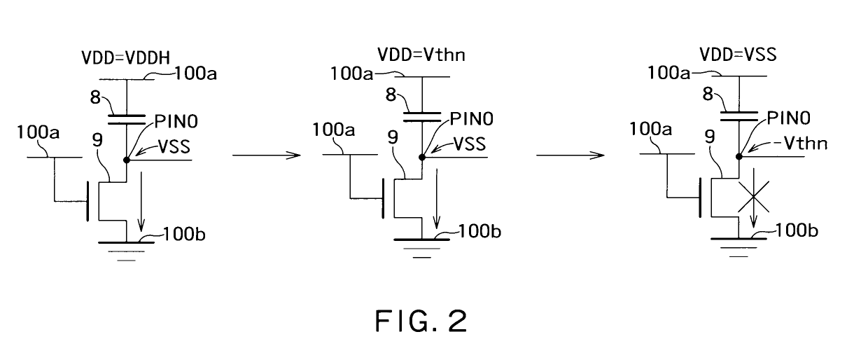

FIG. 2 shows an example of the operation of the voltage generating section A in the power-on reset circuit 100 of FIG. 1.

As shown in FIG. 2, at power-on (when the power supply is turned on), the power supply voltage VDD is equal to the specified value VDDH and the fifth MOS transistor 9 is turned on. Thus the voltage of the second terminal PIN0 is the ground voltage VSS.

After that, at power-off (when the power supply is turned off), the fifth MOS transistor 9 is turned off in the case where the power supply voltage VDD is lower than the threshold voltage Vthn of the fifth MOS transistor. Thus even when the power supply voltage VDD decreases, a potential difference (Vthn−VSS) on the second capacitive element is kept.

Next, when the power supply voltage VDD further decreases and the power supply voltage VDD is equal to the ground voltage VSS, the fifth MOS transistor 9 is kept turned off. As described above, since the potential difference (Vthn−VSS) on the second capacitive element is kept, the second terminal PIN0 has a voltage of −Vthn. In other words, the voltage generating section A generates a negative voltage.

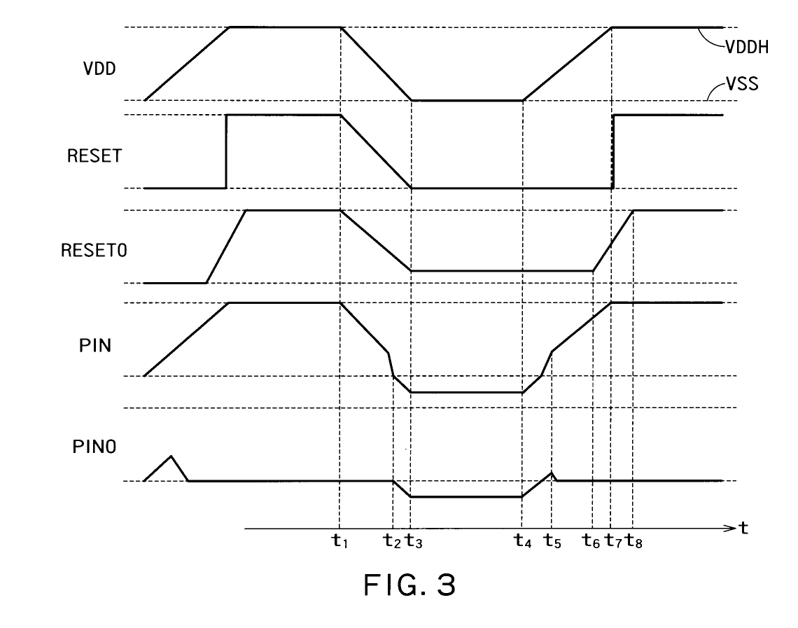

FIG. 3 is a waveform chart showing an example of the signal waveforms of the power-on reset circuit 100 in FIG. 1 when the power supply is repeatedly turned on and off.

As shown in FIG. 3, when the power supply is turned on, the first terminal PIN is pulled up to the power supply voltage VDD because the third MOS transistor 6 is turned on (until time t1). At this point, the power supply voltage VDD is equal to the specified value VDDH and the fifth MOS transistor 9 is turned on. Thus the voltage of the second terminal PIN0 is the ground voltage VSS. Further, the voltage RESET0 of the signal terminal 1 is the power supply voltage VDD, and the reset signal RESET of the output terminal 2 is set at “High” level.

When the power supply is turned off, the lower the power supply voltage VDD, the lower the voltage of the first terminal PIN. Thus the second MOS transistor 5 is turned on and the level of the output signal RESET of the output terminal 2 is reduced as the voltage RESET0 of the signal terminal 1 decreases (from time t1 to time t2). At this point, the third MOS transistor 6 is also turned off.

As has been illustrated in FIG. 2, when the fifth MOS transistor is turned off at time t2 and the voltage of the second terminal PIN0 starts falling below the ground voltage VSS, the fourth MOS transistor 7 is turned on and the first terminal PIN is electrically connected to the second terminal PIN0 (from time t2). Thus the first terminal PIN has a negative voltage.

Hence, the second MOS transistor 5 can reduce the voltage of the signal terminal RESET0 to a voltage obtained by subtracting the threshold voltage Vthn of the fifth MOS transistor 9 from the threshold voltage Vthp of the second MOS transistor 5 (to the ground voltage VSS when the obtained voltage is not higher than the ground voltage VSS) unlike in the prior art (from time t3 to time t4).

When the power supply voltage VDD starts rising at power-on (at time t4), the voltages of the first and second terminals PIN and PIN0 increase, the fifth MOS transistor 9 is turned on, and the fourth MOS transistor 7 is turned off (at time t5). Thus the first terminal PIN is shut off from the second terminal PIN0 (from time t5).

When the power supply voltage VDD increases (the power supply voltage VDD is equal to the specified value VDDH at time t7), the voltage of the first terminal PIN increases (from time t6). Thus the second MOS transistor 5 is turned off. When the voltage RESET0 of the signal terminal 1 exceeds the logic threshold value of the inverter, the level of the output signal RESET from the output terminal 2 changes from “Low” level to “High” level (from time t6 to time t8). At this point, the third MOS transistor 6 is also turned on.

In this way, the power-on reset circuit 100 outputs the reset signal RESET which changes from “Low” level to “High” level as the power supply voltage VDD increases.

As described above, the signal terminal RESET0 has a larger potential difference than in the prior art. Thus the power-on reset circuit 100 can more properly output the reset signal when the power supply is turned on immediately after power- off.

In this way, the power-on reset circuit of the present embodiment can more properly output the reset signal.

### Second Embodiment

The first embodiment described an example of a configuration for generating a negative voltage by means of capacitors and MOS transistors.

A second embodiment will describe another example of the configuration for generating a negative voltage by means of capacitors and MOS transistors.

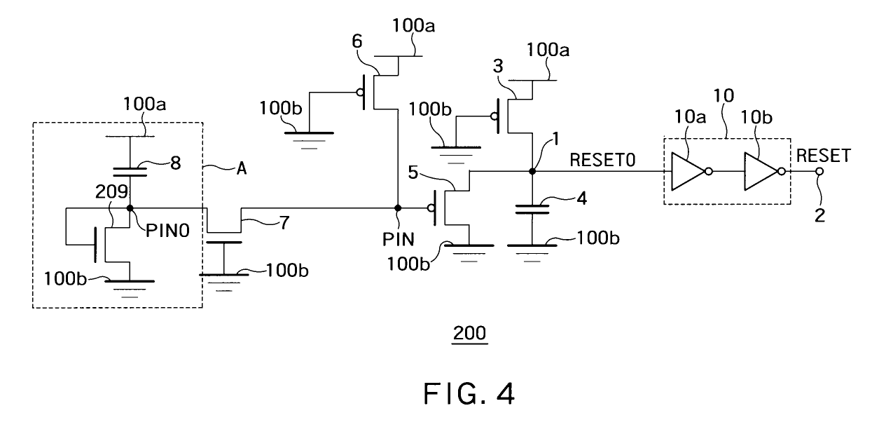

FIG. 4 is a circuit diagram showing the configuration of a power-on reset circuit (semiconductor device) 200 according to the second embodiment which is an aspect of the present invention. In FIG. 4, the same reference numerals as FIG. 1 denote the same configurations as the first embodiment.

As shown in FIG. 4, the power-on reset circuit 200 includes a signal terminal 1, an output terminal 2, a first MOS transistor 3, a first capacitive element 4, a second MOS transistor 5, a third MOS transistor 6, a fourth MOS transistor 7, a second capacitive element 8, a fifth MOS transistor 209, and an inverter circuit 10.

The fifth MOS transistor 209 is diode-connected between a second terminal PIN0 and a second power supply line 100b (the gate is connected to the drain).

The fifth MOS transistor 9 and the second capacitive element 8 constitute a voltage generating section A for generating a negative voltage when the power supply is turned off.

The first to third MOS transistors 3, 5, and 6 preferably have the same threshold voltage Vthp. Further, the fourth and fifth MOS transistors 7 and 209 preferably have the same threshold voltage Vthn. In other words, the MOS transistors of the same conductivity type preferably have the same threshold voltage.

The configurations of the power-on reset circuit 200 other than the fifth MOS transistor 209 are similar to the other configurations of the power-on reset circuit 100 of the first embodiment.

The power-on reset circuit 200 configured thus outputs a reset signal in a similar manner to the power-on reset circuit 100 of the first embodiment.

As described above, in the first embodiment, the gate of the fifth MOS transistor 9 is connected to the first power supply line 100a. Thus the second terminal PIN0 has a negative voltage when the power supply is turned off, so that the fifth MOS transistor 9 has a gate-source voltage of Vthn and a potential difference on the second capacitive element 8 may gradually decrease.

On the other hand, in the second embodiment, the fifth MOS transistor 209 is diode-connected and thus the gate-source voltage of the fifth MOS transistor 209 is fixed at 0 V when the power supply is turned off. Hence, it is possible to keep a potential difference on the second capacitive element 8 for a longer time than in the first embodiment.

With this configuration, the voltage generating section A can output a negative voltage with higher stability, so that a signal terminal RESET0 has a larger potential difference than in the prior art. For this reason, the power-on reset circuit 200 can more properly output the reset signal when the power supply is turned on immediately after power-off.

In this way, the power-on reset circuit of the present embodiment can more properly output the reset signal.

### Third Embodiment

A third embodiment will describe still another example of the configuration for generating a negative voltage by means of capacitors and MOS transistors.

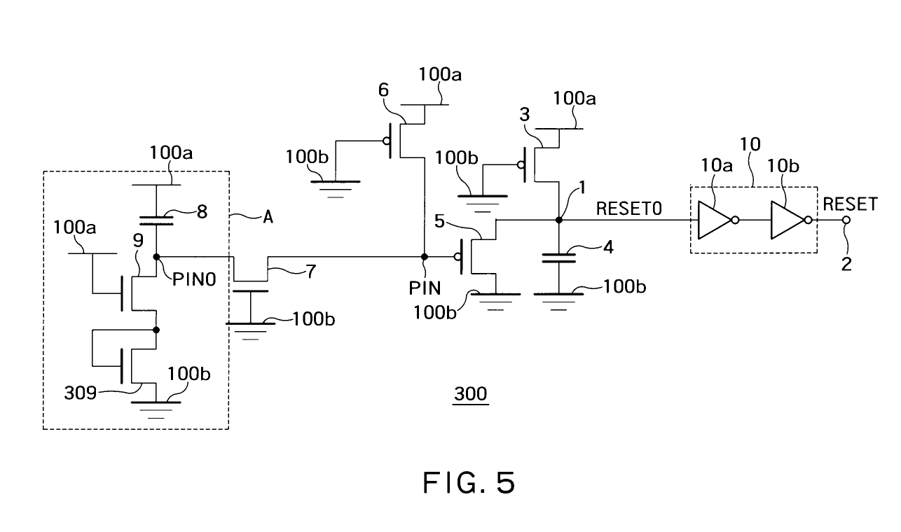

FIG. 5 is a circuit diagram showing the configuration of a power-on reset circuit (semiconductor device) 300 according to the third embodiment which is an aspect of the present invention. In FIG. 5, the same reference numerals as FIG. 1 denote the same configurations as the first embodiment.

As shown in FIG. 5, the power-on reset circuit 300 includes a signal terminal 1, an output terminal 2, a first MOS transistor 3, a first capacitive element 4, a second MOS transistor 5, a third MOS transistor 6, a fourth MOS transistor 7, a second capacitive element 8, a fifth MOS transistor 9, a sixth MOS transistor 309, and an inverter circuit 10. In other words, the power-on reset circuit 300 further includes the sixth MOS transistor 309 unlike the power-on reset circuit 100 of the first embodiment.

The sixth MOS transistor 309 is connected in series with the fifth MOS transistor 9 and is diode-connected between a second terminal PIN0 and a second power supply line 100b (the gate is connected to the drain). Particularly, the sixth MOS transistor 309 is connected between the fifth MOS transistor and the second power supply line 100b.

The fifth MOS transistor 9, the sixth MOS transistor 309, and the second capacitive element 8 constitute a voltage generating section A for generating a negative voltage when the power supply is turned off.

The first to third MOS transistors 3, 5, and 6 preferably have the same threshold voltage Vthp. Further, the fourth to sixth MOS transistors 7, 9, and 309 preferably have the same threshold voltage Vthn. In other words, the MOS transistors of the same conductivity type preferably have the same threshold voltage.

The configurations of the power-on reset circuit 300 other than the sixth MOS transistor 309 are similar to the other configurations of the power-on reset circuit 100 of the first embodiment.

The power-on reset circuit 300 configured thus outputs a reset signal in a similar manner to the power-on reset circuit 100 of the first embodiment.

In this configuration, the fifth MOS transistor 9 of the power-on reset circuit 300 has a source voltage of Vthn and thus the fifth MOS transistor 9 is turned off when a power supply voltage VDD is equal to 2Vthn (twice the threshold voltage of an nMOS transistor). Hence, the voltage generating section A of the power-on reset circuit 300 can output a larger negative voltage than in the first and second embodiments.

With this configuration, the voltage generating section A can output a negative voltage with higher stability, so that a signal terminal RESET0 has a larger potential difference than in the prior art. For this reason, the power-on reset circuit 300 can more properly output the reset signal when the power supply is turned on immediately after power-off.

In this way, the power-on reset circuit of the present embodiment can more properly output the reset signal.

### Fourth Embodiment

A fourth embodiment will describe still another example of the configuration for generating a negative voltage by means of capacitors and MOS transistors.

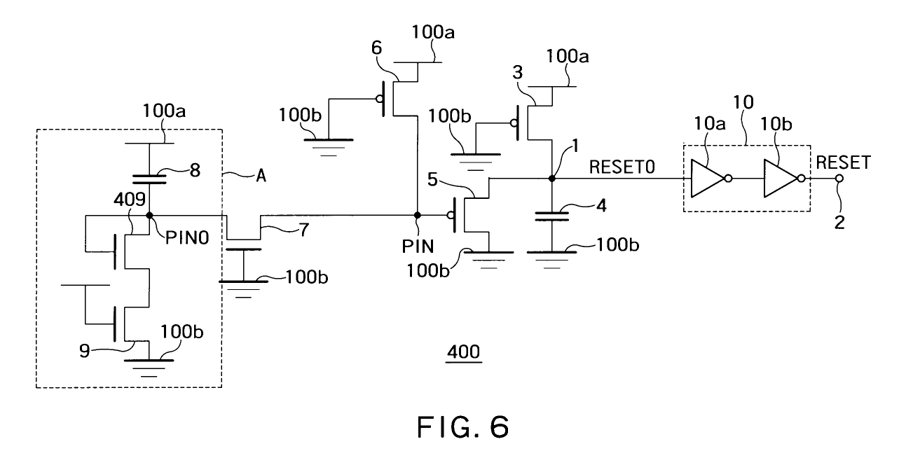

FIG. 6 is a circuit diagram showing the configuration of a power-on reset circuit (semiconductor device) 400 according to the fourth embodiment which is an aspect of the present invention. In FIG. 6, the same reference numerals as FIG. 1 denote the same configurations as the first embodiment.

As shown in FIG. 6, the power-on reset circuit 400 includes a signal terminal 1, an output terminal 2, a first MOS transistor 3, a first capacitive element 4, a second MOS transistor 5, a third MOS transistor 6, a fourth MOS transistor 7, a second capacitive element 8, a fifth MOS transistor 9, a sixth MOS transistor 409, and an inverter circuit 10. In other words, the power-on reset circuit 400 further includes the sixth MOS transistor 409 unlike the power-on reset circuit 100 of the first embodiment.

The sixth MOS transistor 409 is connected in series with the fifth MOS transistor 9 and is diode-connected between a second terminal PIN0 and a second power supply line 100b (the gate is connected to the drain). Particularly, the sixth MOS transistor 409 is connected between the fifth MOS transistor and the second terminal PIN0.

The fifth MOS transistor 9, the sixth MOS transistor 409, and the second capacitive element 8 constitute a voltage generating section A for generating a negative voltage when the power supply is turned off.

The first to third MOS transistors 3, 5, and 6 preferably have the same threshold voltage Vthp. Further, the fourth to sixth MOS transistors 7, 9, and 409 preferably have the same threshold voltage Vthn. In other words, the MOS transistors of the same conductivity type preferably have the same threshold voltage.

The configurations of the power-on reset circuit 400 other than the sixth MOS transistor 409 are similar to the other configurations of the power-on reset circuit 100 of the first embodiment.

The power-on reset circuit 400 configured thus outputs a reset signal in a similar manner to the power-on reset circuit 100 of the first embodiment.

In the third embodiment, the fifth MOS transistor 9 is turned off when a power supply voltage VDD is equal to 2Vthn (twice the threshold voltage of an nMOS transistor). Hence, at a low temperature and a high Vthn, a specified value VDDH is smaller than 2Vthn (twice the threshold voltage of the nMOS transistor) and a potential difference on the second capacitive element 8 is reduced. For this reason, a desired negative voltage may not be obtained at power-off.

In the fourth embodiment, the fifth MOS transistor 9 is turned on at power-on, so that a potential difference on the second capacitive element 8 is obtained by subtracting the threshold voltage Vthn of the sixth MOS transistor 409 from the power supply voltage VDD. After that, the fifth MOS transistor 9 is turned off when the power supply voltage VDD decreases at power-off. Thus it is possible to obtain a larger negative voltage than in the first and second embodiments.

With this configuration, the voltage generating section A can output a negative voltage with higher stability, so that a signal terminal RESET0 has a larger potential difference than in the prior art. For this reason, the power-on reset circuit 400 can more properly output the reset signal when the power supply is turned on immediately after power-off.

In this way, the power-on reset circuit of the present embodiment can more properly output the reset signal.

### Fifth Embodiment

A fifth embodiment will describe still another example of the configuration for generating a negative voltage by means of capacitors and MOS transistors.

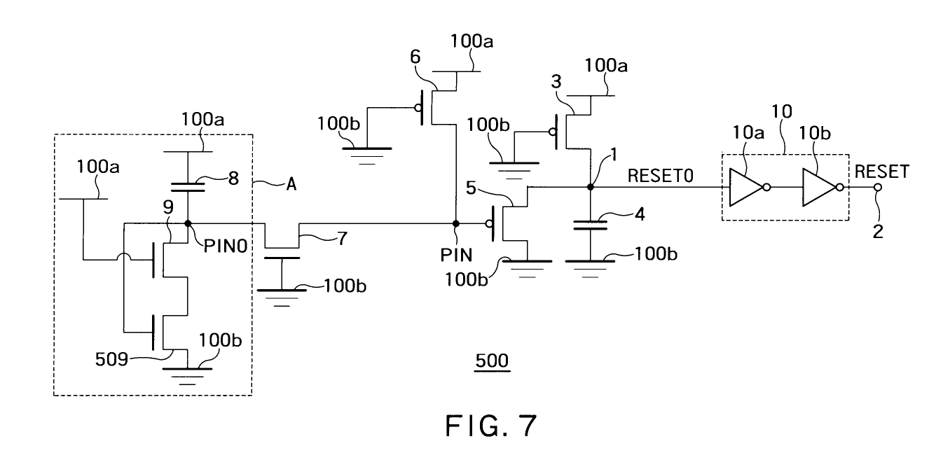

FIG. 7 is a circuit diagram showing the configuration of a power-on reset circuit (semiconductor device) 500 according to the fifth embodiment which is an aspect of the present invention. In FIG. 7, the same reference numerals as FIG. 1 denote the same configurations as the first embodiment.

As shown in FIG. 7, the power-on reset circuit 500 includes a signal terminal 1, an output terminal 2, a first MOS transistor 3, a first capacitive element 4, a second MOS transistor 5, a third MOS transistor 6, a fourth MOS transistor 7, a second capacitive element 8, a fifth MOS transistor 9, a sixth MOS transistor 509, and an inverter circuit 10. In other words, the power-on reset circuit 500 further includes the sixth MOS transistor 509 unlike the power-on reset circuit 100 of the first embodiment.

The sixth MOS transistor 509 is connected between the end (source) of the fifth MOS transistor 9 and a second power supply line 100b and has the gate connected to a second terminal PIN0.

The fifth MOS transistor 9, the sixth MOS transistor 509, and the second capacitive element 8 constitute a voltage generating section A for generating a negative voltage when the power supply is turned off.

The first to third MOS transistors 3, 5, and 6 preferably have the same threshold voltage Vthp. Further, the fourth to sixth MOS transistors 7, 9, and 509 preferably have the same threshold voltage Vthn. In other words, the MOS transistors of the same conductivity type preferably have the same threshold voltage.

The configurations of the power-on reset circuit 500 other than the sixth MOS transistor 509 are similar to the other configurations of the power-on reset circuit 100 of the first embodiment.

The power-on reset circuit 500 configured thus outputs a reset signal in a similar manner to the power-on reset circuit 100 of the first embodiment.

In this configuration, the fifth MOS transistor 9 of the power-on reset circuit 500 is turned on at power-on, so that a potential difference on the second capacitive element 8 is obtained by subtracting the threshold voltage Vthn of the sixth MOS transistor 509 from a power supply voltage VDD. After that, the fifth MOS transistor 9 is turned off when the power supply voltage VDD decreases at power-off. Thus the voltage generating section A of the power-on reset circuit 500 can output a larger negative voltage than in the first and second embodiments.

With this configuration, the voltage generating section A can output a negative voltage with higher stability, so that a signal terminal RESET0 has a larger potential difference than in the prior art. For this reason, the power-on reset circuit 500 can more properly output the reset signal when the power supply is turned on immediately after power-off.

In this way, the power-on reset circuit of the present embodiment can more properly output the reset signal.

What is claimed is:

1. A semiconductor device comprising:
a signal terminal;
an output terminal that outputs a reset signal according to a voltage of the signal terminal;
a first MOS transistor of a first conductivity type, the first MOS transistor being connected between the signal terminal and a first power supply line and having a gate connected to a second power supply line;
a first capacitive element connected between the signal terminal and the second power supply line;
a second MOS transistor of the first conductivity type, the second MOS transistor being connected between the signal terminal and the second power supply line and having a gate connected to a first terminal;
a third MOS transistor of the first conductivity type, the third MOS transistor being connected between the first power supply line and the first terminal and having a gate connected to the second power supply line;
a fourth MOS transistor of a second conductivity type, the fourth MOS transistor being connected between the first terminal and a second terminal and having a gate connected to the second power supply line;
a second capacitive element connected between the first power supply line and the second terminal; and
a fifth MOS transistor of the second conductivity type, the fifth MOS transistor being connected between the second terminal and the second power supply line and having a gate connected to the first power supply line.

2. The semiconductor device according to claim 1, further comprising:
a sixth MOS transistor that is connected in series with the fifth MOS transistor between the second terminal and the second power supply line and is diode-connected.

3. The semiconductor device according to claim 1, further comprising:
a sixth MOS transistor of the second conductivity type, the sixth MOS transistor being connected between the fifth MOS transistor and the second power supply line and having a gate connected to the second terminal.

4. The semiconductor device according to claim 1, further comprising:
an inverter circuit having a input side connected to the signal terminal and a output side connected to the output terminal, including at least an inverter, and outputting the reset signal to the output terminal according to the voltage of the signal terminal.

5. The semiconductor device according to claim 2, further comprising:
an inverter circuit having a input side connected to the signal terminal and a output side connected to the output terminal, including at least an inverter, and outputting the reset signal to the output terminal according to the voltage of the signal terminal.

6. The semiconductor device according to claim 3, further comprising:
an inverter circuit having a input side connected to the signal terminal and a output side connected to the output terminal, including at least an inverter, and outputting the reset signal to the output terminal according to the voltage of the signal terminal.

7. The semiconductor device according to claim 1, wherein the first conductivity type is a p-type,
the second conductivity type is an n-type,
the first power supply line is connected to a power supply, and
the second power supply line is connected to a ground.

8. The semiconductor device according to claim 1, wherein the first to third MOS transistors have a first threshold voltage, and
the fourth and fifth MOS transistors have a second threshold voltage.

9. The semiconductor device according to claim 7, wherein a power supply voltage is equal to a ground voltage when the power supply is turned off.

10. The semiconductor device according to claim 1, wherein the first conductivity type is an n-type,
the second conductivity type is a p-type,
the first power supply line is connected to a ground, and
the second power supply line is connected to a power supply.

11. The semiconductor device according to claim 10, wherein a power supply voltage is equal to a ground voltage when the power supply is turned off.

12. A semiconductor device comprising:
a signal terminal;
an output terminal that outputs a reset signal according to a voltage of the signal terminal;
a first MOS transistor of a first conductivity type, the first MOS transistor being connected between the signal terminal and a first power supply line and having a gate connected to a second power supply line;
a first capacitive element connected between the signal terminal and the second power supply line;
a second MOS transistor of the first conductivity type, the second MOS transistor being connected between the signal terminal and the second power supply line and having a gate connected to a first terminal;
a third MOS transistor of the first conductivity type, the third MOS transistor being connected between the first power supply line and the first terminal and having a gate connected to the second power supply line;
a fourth MOS transistor of a second conductivity type, the fourth MOS transistor being connected between the first terminal and a second terminal and having a gate connected to the second power supply line;
a second capacitive element connected between the first power supply line and the second terminal; and
a fifth MOS transistor being connected between the second terminal and the second power supply line and being diode-connected.

13. The semiconductor device according to claim 12, further comprising:
an inverter circuit having a input side connected to the signal terminal and a output side connected to the output terminal, including at least an inverter, and outputting the reset signal to the output terminal according to the voltage of the signal terminal.

14. The semiconductor device according to claim 12, wherein the first conductivity type is a p-type,
the second conductivity type is an n-type,
the first power supply line is connected to a power supply, and
the second power supply line is connected to a ground.

15. The semiconductor device according to claim 12, wherein the first to third MOS transistors and the fifth MOS transistor of the first conductivity type have a first threshold voltage, and
the fourth transistor have a second threshold voltage.

16. The semiconductor device according to claim 12, wherein the first to third MOS transistors have a first threshold voltage, and
the fourth transistor and the fifth MOS transistor of the second conductivity type have a second threshold voltage.

17. The semiconductor device according to claim 14, wherein a power supply voltage is equal to a ground voltage when the power supply is turned off.

18. The semiconductor device according to claim 12, wherein the first conductivity type is an n-type,
the second conductivity type is a p-type,
the first power supply line is connected to a ground, and
the second power supply line is connected to a power supply.

19. The semiconductor device according to claim 18, wherein a power supply voltage is equal to a ground voltage when the power supply is turned off.
